(19) United States
(12) Patent Application Publication
(10) Pub. No.: US 2014/0240030 A1
(43) Pub. Date: Aug. 28, 2014

(54) Semiconductor Switch Circuit

(71) Applicant: Kabushiki Kaisha Toshiba, Tokyo (JP)

(72) Inventor: Takayuki Teraguchi, Kanagawa-ken (JP)

(21) Appl. No.: 13/942,230

(22) Filed: Jul. 15, 2013

(30) Foreign Application Priority Data
Feb. 26, 2013 (JP) P2013-035600

(51) Int. Cl. H03K 17/30; H03K 17/00

(52) U.S. Cl. CPC H03K 17/302; H03K 17/007
USPC 327/436

(57) ABSTRACT

A semiconductor switch circuit includes first semiconductor switch units and second semiconductor switch units. The first semiconductor switch units each have a first threshold and two first ends. One first end is connected to a common terminal. The second semiconductor switch units each have a second threshold and two second ends. One second end is connected to the other first end of the first semiconductor switch units. The second threshold is lower than the first threshold.

### CROSS REFERENCE TO RELATED APPLICATION

This application is based upon and claims the benefit of priority from the prior Japanese Patent Application 2013-035600, filed on Feb. 26, 2013, the entire contents of which are incorporated herein by reference.

### FIELD

Embodiments described herein are generally related to a semiconductor switch circuit.

### BACKGROUND

High-frequency switches are used for mobile communication terminals in order to switch antennas for transmitting or receiving.

In the background art, the high-frequency switch employs a semiconductor switch circuit including insulated gate field effect transistors (MOS transistors) that are connected in series.

The MOS transistors connected in series have the same parameters including a threshold value, a gate length, and a gate width.

When a semiconductor switch is a multiport semiconductor switch circuit having one output (input) terminal and two or more input (output) terminals, the MOS transistors are connected so as to be a multistage connection in a tree structure. The semiconductor switch circuit having the tree structure effectively reduces insertion loss.

Meanwhile, in the semiconductor switch circuit having the tree structure, voltage of high-frequency signals applied to off-state MOS transistors have larger voltage amplitude at the first stage than at the second stage.

Unfortunately, excessively large voltage amplitude of the high-frequency signals does not allow the MOS transistors to keep off-states, thereby deteriorating distortion characteristic of the high-frequency signals.

### BRIEF DESCRIPTION OF THE DRAWINGS

The accompanying drawings, which are incorporated in and constitute a part of this specification, illustrate embodiments of the invention and together with the description, serve to explain the principles of the invention.

FIG. 1 is a block diagram showing a semiconductor switch circuit according to a first embodiment.

FIGS. 2A and 2B are circuit diagrams showing semiconductor switch units in the semiconductor switch circuit according to the first embodiment.

FIG. 3 is a circuit diagram showing a bias circuit in the semiconductor switch circuit according to the first embodiment.

FIG. 4 is a graph showing a relation between the number of branches and voltage amplitude of high-frequency signals in the semiconductor switch circuit according to the first embodiment.

FIG. 5 is a graph showing a relation between the number of branches and a margin voltage Voff for the voltage amplitude of the high-frequency signals in the semiconductor switch circuit according to the first embodiment.

FIG. 6 is a graph showing distortion characteristics of the semiconductor switch circuit of the first embodiment in comparison with a semiconductor switch circuit of a comparative example.

FIG. 7 is a block diagram showing another semiconductor switch circuit according to the first embodiment.

FIG. 8 is a block diagram showing another semiconductor switch circuit according to the first embodiment.

FIG. 9 is a block diagram showing a semiconductor switch circuit according to a second embodiment.

FIG. 10 is a circuit diagram showing a bias circuit according to the second embodiment.

FIG. 11 is a block diagram showing another semiconductor switch circuit according to the second embodiment.

### DETAILED DESCRIPTION

According to one embodiment, a semiconductor switch circuit includes first semiconductor switch units and second semiconductor switch units. The first semiconductor switch units each have a first threshold and two first ends. One first end is connected to a common terminal. The second semiconductor switch units each have a second threshold and two second ends. One second end is connected to the other first end of the first semiconductor switch units. The second threshold is lower than the first threshold.

Hereinafter, embodiments will be described with reference to drawings. In the drawings, same reference characters denote the same or similar portions.

### First Embodiment

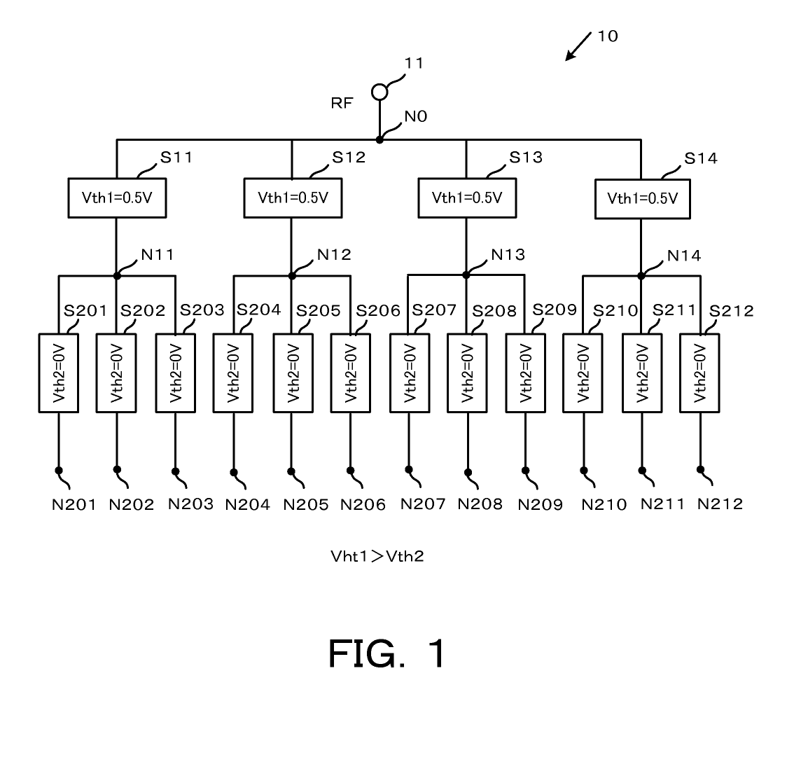

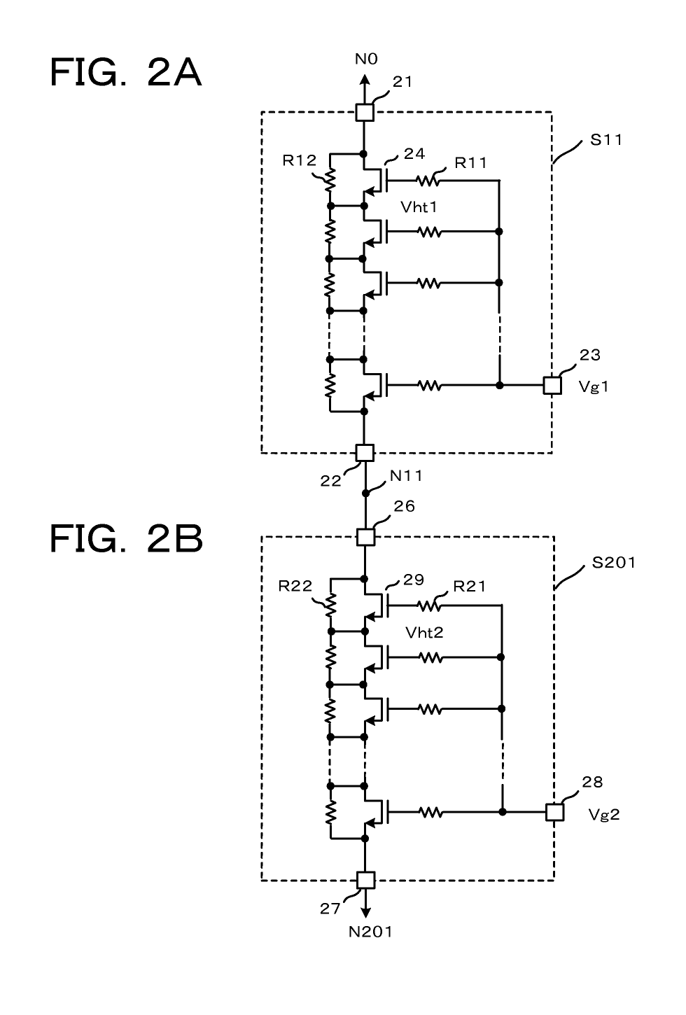

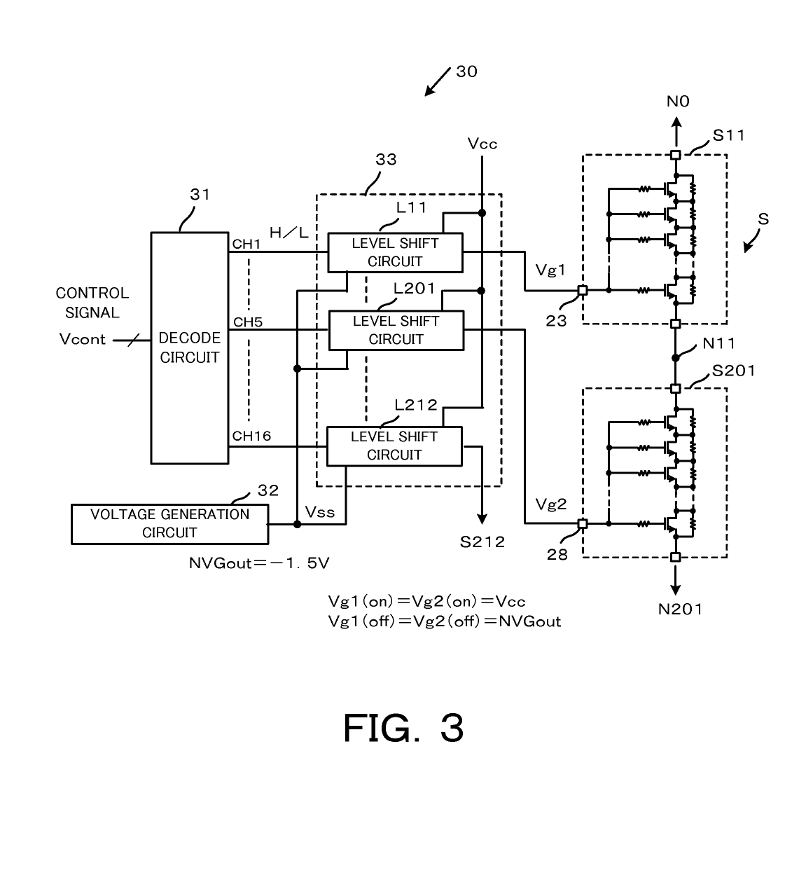

A semiconductor switch circuit in accordance with a first embodiment will be described with reference to FIGS. 1 to 3. FIG. 1 is a circuit diagram showing the semiconductor switch circuit in accordance with the first embodiment. FIGS. 2A and 2B are circuit diagrams showing semiconductor switch units in the semiconductor switch circuit. FIG. 3 is a circuit diagram showing a bias circuit in the semiconductor switch circuit.

The semiconductor switch circuit of the embodiment is a multiport bidirectional switch circuit with one input (output) terminal (common terminal) and two or more output (input) terminals (respective terminals), and is also a high-frequency switch circuit to switch an antenna for the transmitting or receiving of a mobile communication terminal.

As shown in FIG. 1, the semiconductor switch circuit 10 of the embodiment includes two or more semiconductor switch units S that are connected in a tree structure. In the detailed description, two or more switch units are denoted as a whole by semiconductor switch units “S,” and each switch unit is denoted by an individual numeral in contact with S.

The tree structure is substantially one of data structures. In the tree structure, one element (node) has two or more child-elements, each child-element has two or more grandchild-elements, and each grandchild-element further has two or more subordinate elements. The tree structure is analogous to a tree in which a stem has two or more branches each having two or more leaves.

The tree structure has two stages, in which 4 second nodes N11 to N14 branch off from a first node N0, and third nodes N201 to N212 branch off 3 by 3 from each second node. The third nodes N201 to N212 are undermost nodes without under nodes. The first to third nodes will be referred to simply as “nodes.”

The first stage of the tree structure has 4 semiconductor switch units S11 to S14 (first semiconductor switch units). The second stage of the tree structure has 12 semiconductor switch units S201 to S212 (second semiconductor switch units).

The semiconductor switch unit S11 is connected between the node NO and the node N11. The semiconductor switch unit S12 is connected between the node NO and the node N12. The semiconductor switch unit S13 is connected between the node NO and the node N13. The semiconductor switch unit S14 is connected between the node NO and the node N14.

The semiconductor switch unit S201 is connected between the node N11 and the node N201. The semiconductor switch unit 5202 is connected between the node N11 and the node N202. The semiconductor switch unit S203 is connected between the node N11 and the node N203. The semiconductor switch units S204 to S212 are connected as well as the semiconductor switch units S201 to S203. The specific description will not be repeated.

No semiconductor switch units are connected to the nodes N201 to N212 because of just the two stages in the tree structure. A common terminal 11 is connected to the node N0 to input or output high-frequency signals RF. The common terminal 11 is connected to an antenna, for example. Corresponding terminals (not shown) are connected to the respective nodes N201 to N212. The corresponding terminals are connected to circuits including a transmitter circuit and a receiver circuit.

In the semiconductor switch circuit 10 having a tree structure, the semiconductor switch units S are driven such that any one of the semiconductor switch units S11 to S14 at the first stage is tuned on and any one of the semiconductor switch units S201 to S212 at the second stage is turned on.

As a result, a current path is formed so as to cause high-frequency signals RF to pass through the semiconductor switch units having been in an on state. High-frequency signals RF are inputted into the common terminal 11 to be outputted from any one of the respective terminals. High-frequency signals RF are inputted into any one of the respective terminals to be outputted from the common terminal 11.

A configuration of the semiconductor switch units S will be described below. As shown in FIG. 2A, the semiconductor switch unit S11 at the first stage includes a first terminal 21 connected to the node N0, a second terminal 22 connected to the node N11, and a control terminal 23 into which a gate voltage (first control voltage) Vg1 is inputted.

The semiconductor switch unit S11 includes two or more n-channel insulated gate field effect transistors 24 (hereinafter, referred to as MOS transistors) which are connected in serial. The MOS transistors 24 have a gate width Wg of 4 mm and a threshold (first threshold) Vth1 of 0.5 V.

The drain electrode of the MOS transistor 24, which is located at one end of the series circuit of the MOS transistors 24, is connected to the first terminal 21. The source electrode of the MOS transistor 24, which is located at the other end of the series circuit of the MOS transistors 24, is connected to to second terminal 22.

A first resistance R11 is connected between the gate electrode of each MOS transistor 24 and the control terminal 23. A second resistance R12 is connected between the drain electrode and the source electrode of each MOS transistor 24.

The first, second and third terminals 21, 22, and 23 are referred to as a drain terminal, a source terminal, and a gate terminal, respectively. The semiconductor switch units S12 to S14 are the same as the semiconductor switch unit S11. The same description will not be repeated.

As shown in FIG. 2B, the semiconductor switch unit S201 at the second stage is substantially the same as the semiconductor switch unit S11 at the first stage. A different point is that the threshold (second threshold) Vth2 of a MOS transistor is lower than the threshold Vth1.

The semiconductor switch unit S201 includes a first terminal 26 connected to the node N11, a second terminal 27 connected to the node N201, and a control terminal 28 into which a gate voltage (second control voltage) Vg2 is inputted.

In the semiconductor switch unit S201, two or more MOS transistors 29 are connected in serial. The MOS transistors 29 have a gate width Wg of 4 mm and a threshold (second threshold) Vth2 of 0 V, for example.

The drain electrode of the MOS transistor 29, which is located at one end of a series circuit of the MOS transistors 29, is connected to the first terminal 26. The source electrode of the MOS transistor 29, which is located at the other end of the series circuit of the MOS transistors 29, is connected to the second terminal 27.

A first resistance R21 is connected between the gate electrode of each MOS transistor 29 and the control terminal 28. A second resistance R22 is connected between the drain electrode and the source electrode of each MOS transistor 29.

The series-connected MOS transistors 24 ensure a withstanding voltage over maximum voltage amplitude of high-frequency signals RF inputted into the semiconductor switch unit S11.

The first resistances R11 are connected to the respective gates of the MOS transistors 24 in order to stabilize switching operation of the MOS transistors 24. The first resistances R11 are so high that high-frequency signals RF do not leak to a bias circuit which will be described later.

The second resistances R21 are breeder resistances that allow high-frequency current to slightly pass through the respective MOS transistors 24 having been in a off state, and are used to average voltage amplitude of high-frequency signals RF applied to the respective MOS transistors 24. The second resistances R21 are so high that high-frequency signals RF do not bypass the MOS transistors 24.

The above description is just as valid for the MOS transistors 29, the first resistances R21, and the second resistance R22. The same description will not be repeated.

As shown in FIG. 3, the bias circuit 30 is configured to output a gate voltage Vg(on) of, e.g., 3 V, which is higher than a threshold of MOS transistors, to a control terminal of a semiconductor switch unit to be on-state; and to output a gate voltage Vg(off) of, e.g., −1.5 V, which is lower than the threshold of the MOS transistors, to the control terminal of the semiconductor switch

The bias circuit 30 includes a decode circuit 31, a voltage generation circuit 32, and a voltage output circuit 33. The decode circuit 31 decodes a control signal Vcont showing a state of the semiconductor switch units S to output a high level signal or a low level signal in accordance with a corresponding state of the semiconductor switch units S. The voltage generation circuit 32 generates a gate voltage Vg(off). In accordance with the decoded results, the voltage output circuit 33 outputs a gate voltage Vg(on) to the semiconductor switch units S to be on-state, and outputs a gate voltage Vg(off) to the semiconductor switch units S to be off-state.

A control signal Vcont is a 6-bit binary signal. Upper two bits of the 6-bit binary signal indicate which one of the semiconductor switch units S11 to S14 is on-state, and lower bits of the 6-bit binary signal indicate which one of the semiconductor switch units S201 to S212 is on-state.

The decode circuit 31 converts the upper two bits and the lower four bits into corresponding binary-coded decimals (BCD) to output 16-channel signals. Each of the 16-channel signals is high level or low level in accordance with the corresponding state of the semiconductor switch units S.

The voltage generation circuit 32 includes a charge pump circuit and a clock-signal generation circuit to generate a voltage NVGout of, e.g., −1.5 V.

The voltage output circuit 33 includes level-shift circuits L11 to L14 and level-shift circuits L201 to L212. The level-shift circuits L12 to L14 and the level-shift circuits L202 to L211 are not shown in FIG. 3.

Each of the level-shift circuits L11 to L14 and L201 to L212 is supplied with a voltage Vcc (>0V) at a power supply terminal thereof, and supplied with a voltage NVGout (Vss) at a ground terminal thereof.

Each of the level-shift circuits L11 to L14 and L201 to L212 converts a logic level into, e.g., a high level of the voltage Vcc or a low level of the voltage NVGout in accordance with a high-level signal or a low-level signal that has been supplied from the decode circuit 31.

Each of the level-shift circuits L11 to L14 and L201 to L212 can be configured to have a pair of PMOS transistors and a pair of NMOS transistors that is complementarily connected to the pair of the PMOS transistors.

Operation of the semiconductor switch circuit 10 will be described below. A current path for high-frequency signals RF is formed by an on-state semiconductor switch unit of the semiconductor switch units S11 to S14 at the first stage and an on-state semiconductor switch unit of the semiconductor switch units S201 to S212 at the second stage. The on-state semiconductor switch units have so low on-resistances that a voltage drop of the high-frequency signals RF does not occur.

In contrast, the other off-state semiconductor switch units function as capacitive elements including a capacitance between drain and source, a capacitance between drain and gate, and a capacitance between gate and source. A voltage of the high frequency signals applied to the semiconductor switch circuit 10 is divided into two voltages in accordance with the capacitance of the off-state semiconductor switch units at the first stage and the capacitance of the off-state semiconductor switch units at the second stage. The two divided voltages are applied to the off-state semiconductor switch units at the respective stages.

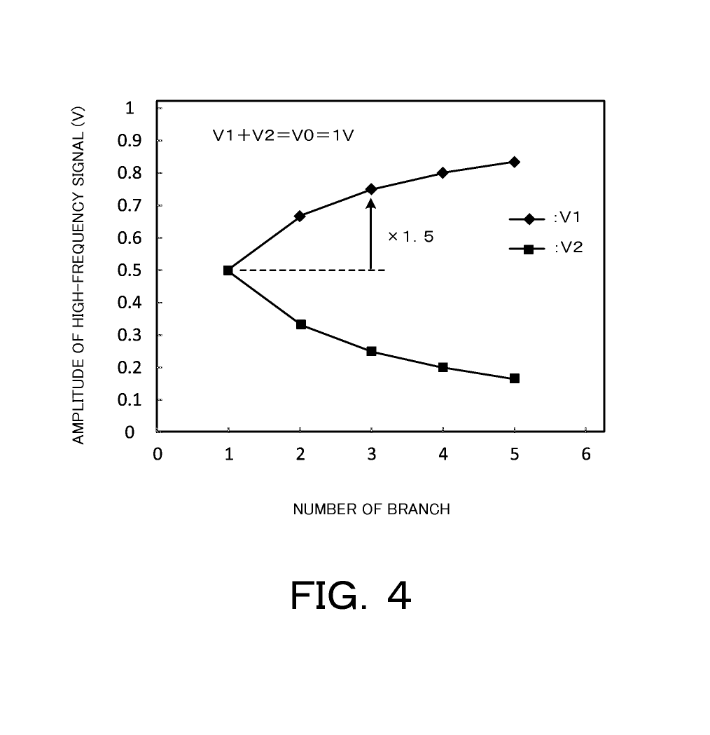

FIG. 4 is a graph showing a relation between the number of branches of each node at the second stage and voltage amplitude of a high-frequency signal RF applied to the semiconductor switch circuit. The horizontal axis denotes the number of branches of each node at the second stage. The vertical axis denotes voltage amplitude of high-frequency signals RF applied.

The voltage amplitude of the high-frequency signals RF is denoted by V0, the voltage amplitude of the high-frequency signals RF applied to the off-state semiconductor switch units at the first stage is denoted by V1, and the voltage amplitude of the high-frequency signals RF which is applied to the off-state semiconductor switch units at the second stage is denoted by V2. V1 and V2 satisfy a relation of V1+V2=V0. The voltage amplitude of the high-frequency signals RF is assumed to a half of a peak-to-peak voltage Vp-p of a high-frequency signal RF.

As shown in FIG. 4, the capacitance of the second stage increases in proportion to the number of the branches of each node at the second stage, thereby increasing V1 and decreasing V2. In the semiconductor switch circuit 10 shown in FIG. 1, the number of the branches of each node at the second stage is 3, thereby yielding V1=0.75 V and V2=0.25 V, provided that V0=1 V.

The voltage amplitude of the high-frequency signals RF applied to the off-state semiconductor switch units at the first stage is 3 times (=0.75/0.25) larger than the corresponding voltage amplitude at the second stage. The voltage amplitude of the high-frequency signals RF applied to the first stage when each node of the second stage has three branches is 1.5 times (=0.75/0.5) larger than the voltage amplitude applied to the first stage when each node of the second stage has just one branch.

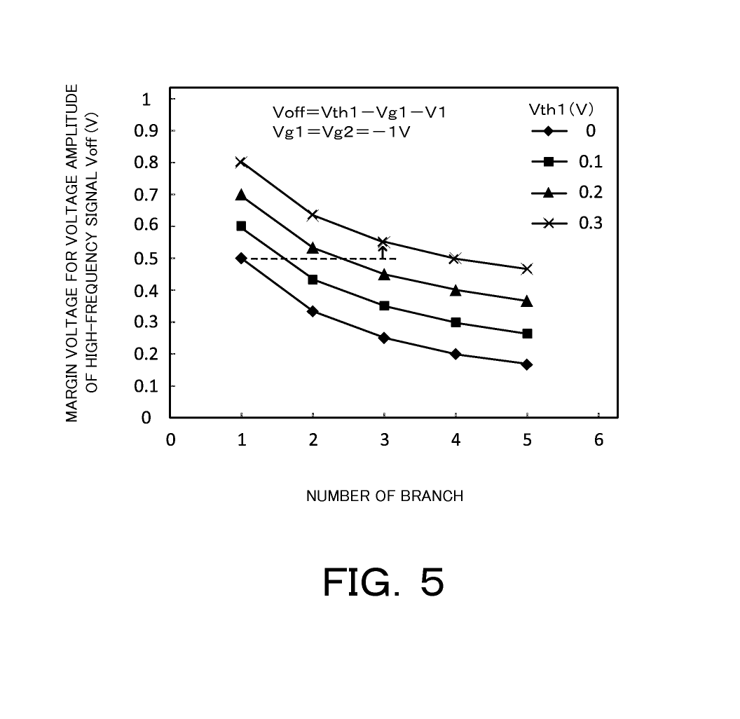

FIG. 5 is a graph showing a relation between the number of branches of each node at the second stage and a margin voltage Voff for the voltage amplitude of the high-frequency signals RF applied to MOS transistors 24 included in each off-state semiconductor switch unit at the first stage. In the graph, a threshold Vth1 of the MOS transistors 24 is treated as parameters.

The margin voltage Voff describes a margin to maintain off states of the MOS transistors 24 when voltage amplitude (signal amplitude) V1 of the high-frequency signal RF is superimposed on a gate voltage Vg1(off), and is expressed by the equation (1) defined as

Voff=Vth1−Vg1−V1 (1)

When the margin voltage Voff for the signal amplitude is positive, the MOS transistors 24 are in an off state. When the margin voltage Voff for the signal amplitude is negative, the signal amplitude that exceeds the threshold Vth1 leaks so that the high-frequency signals RF partially pass through the MOS transistors 24. When the margin voltage Voff for the signal amplitude is positive and near zero, variation in the threshold Vth1 causes the high-frequency signals RF to measurably pass through the MOS transistors 24. The margin voltage Voff above a certain level is needed to prevent the high-frequency signals RF from leaking through the MOS transistors 24.

When the leakage of the high-frequency signal RF through the MOS transistors 24 becomes too much to neglect, signal-distortion characteristic of the semiconductor switch circuit 10 deteriorates to worsen distortion in the high-frequency signals RF.

FIG. 5 shows changes in the margin voltage Voff with the number of the branches at the second stage, provided that both the gate voltages Vg1 and Vg2 are −1 V and the threshold Vth1 is set to 0 V, 0.1 V, 0.2 V, or 0.3 V. As shown in FIG. 5, the increase in the number of the branches increases the voltage amplitude V1 shown in FIG. 4, thereby reducing the margin voltage Voff. The increase in the threshold Vth1 increases the margin voltage Voff at the same number of the branches.

When the threshold Vth1 is 0 V and when the number of the branches is equal to 1, i.e., each node does not branch at the second stage, the margin voltage Voff is 0.5 V, i.e., sufficient margin voltage Voff is provided. In contrast, when the threshold Vth1 is 0 V and when the number of the branches is equal to 3, the margin voltage Voff is 0.25 V, thereby leading to a decrease in

An increase in the threshold Vth1 of up to 0.3 V causes the margin voltage Voff to reach 0.55 V. The margin voltage Voff at 3 branches is equal to or more than the margin voltage Voff at just one branch, thereby enabling it to obtain sufficient margin voltage Voff.

Making the threshold Vth1 higher than the threshold Vth2 allows it to prevent a high-frequency signal RF from passing through the off-state MOS transistors 24. As a result, the distortion characteristic of the semiconductor switch circuit 10 is improved, and the distortion of a high-frequency signal RF is reduced.

An increase in the number of the branches reduces V2, thereby causing a high-frequency signal RF passing through the MOS transistors 29 to be negligibly small.

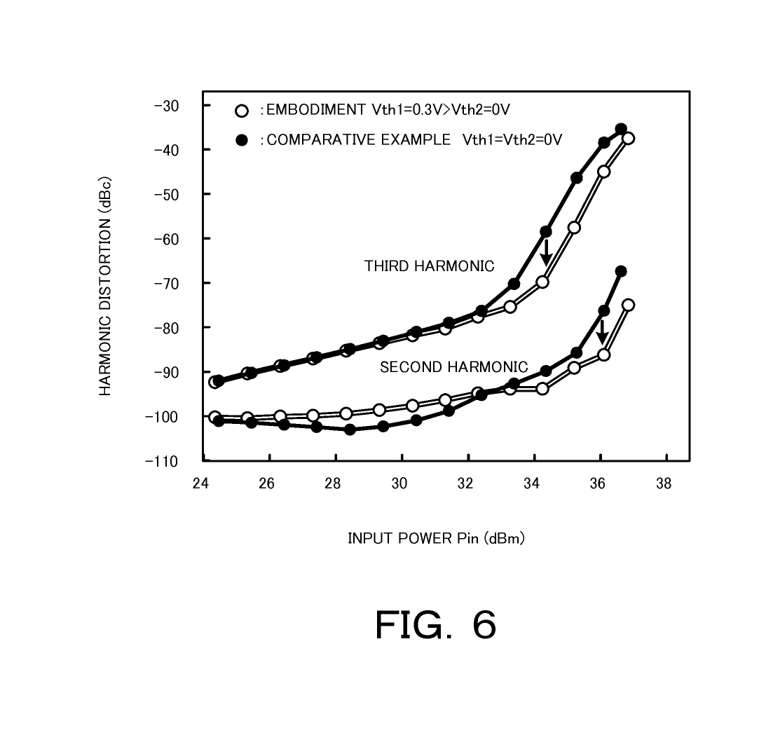

FIG. 6 is a graph showing a simulation of the distortion characteristic of a high-frequency signal RF performed on the semiconductor switch circuit 10 in comparison with a semiconductor switch circuit of a comparative example. The horizontal axis denotes input electric power of the high-frequency signal RF, and the vertical axis denotes second-order harmonic distortion and third-order harmonic distortion.

The simulation conditions are set as:
the thresholds Vth1 and Vth2 are 0.3 V and 0 V, respectively, in the semiconductor switch circuit 10; and
both the thresholds Vth1 and Vth2 are 0 V in the semiconductor switch circuit of the comparative example.

As shown in FIG. 6, the second-order harmonic distortion and the third-order harmonic distortion increase slightly as input power Pin starts to increase. The second-order harmonic distortion and the third-order harmonic distortion rapidly increase from somewhere near the input power Pin exceeding a certain value (approximately 32 dBm). The third-order harmonic distortion is higher than the second-order harmonic distortion.

The increase in the harmonic distortion arises from the fact that the increase in the input electric power Pin (increase in V1) decreases the margin voltage Voff to cause the high-frequency signal RF passing through the MOS transistors 24 to increase. The high-frequency signal RF passing through the MOS transistors 24 slightly increases at low input power, but rapidly increases over an input power range exceeding a certain value.

The simulation reveals that the semiconductor switch circuit 10 reduces the second-order harmonic distortion and the third-order harmonic distortion more effectively than the semiconductor switch circuit of the comparative example. The second-order harmonic distortion is reduced by 5 to 10 dBc, and the third-order harmonic distortion is reduced by 5 to 13 dBc.

This is due to the fact that the threshold Vth1 of the MOS transistors 24 is 0.3 V higher in the embodiment than in the comparative example, i.e., the margin voltage Voff is higher in the embodiment than in the comparative example.

Making the threshold Vth1 of the MOS transistors 24 higher than the threshold Vth2 of the MOS transistors 29 is performed by modifying parameters including a dose of impurity ions for channels, a gate length, and a thickness of a gate insulating film.

As described above, in the semiconductor switch circuit 10 of the embodiment, two or more semiconductor switch units S are electrically connected so as to form a tree structure in which two or more nodes (elements) repeatedly branch off from each node. The threshold Vth1 of the MOS transistors 24 included in the semiconductor switch units S11 to S14 is higher than the threshold Vth2 of the MOS transistors 29 included in the semiconductor switch units S201 to S212.

In other words, the threshold Vth1 of the MOS transistors 24 of the semiconductor switch units S11 to S14 on the side of the node NO is higher than the threshold Vth2 of the MOS transistors 29 of the semiconductor switch units S201 to S212 on the opposite side of the node N0.

As a result, also when the voltage amplitude V0 of a high-frequency signal RF increases, the high-frequency signal RF passing through the MOS transistors 24 is reduced. Thus, the semiconductor switch circuit with little high-frequency distortion is obtained.

In the description of the embodiment, the semiconductor switch circuit 10 has the tree structure such that four nodes N11 to N14 branch off from a node N0 and three nodes further branch off from each of the four nodes N11 to N14. Alternatively, the semiconductor switch circuit 10 may have a different tree structure. The same result of the embodiment may be obtained in the semiconductor switch circuit with the different tree structure.

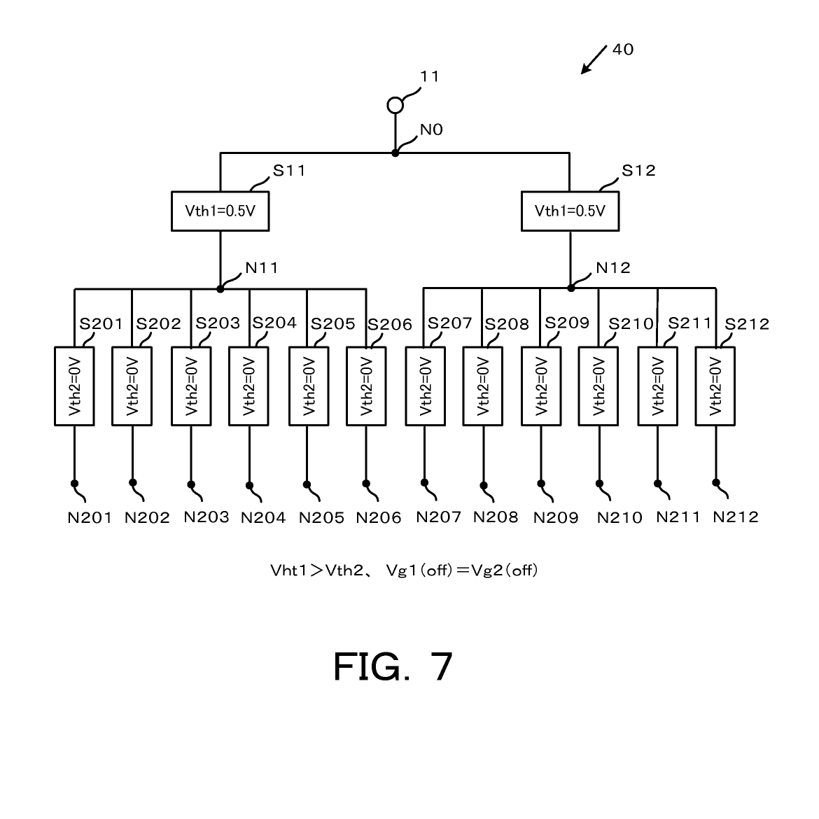

FIG. 7 is a block diagram showing a semiconductor switch circuit with another tree structure. As shown in FIG. 7, a semiconductor switch circuit 40 has a tree structure in which two nodes N11 and N12 branch off from a node N0 and six nodes branch off from each of the two nodes N11 and N12.

The semiconductor switch circuit 40 operates as well as the semiconductor switch circuit 10 shown in FIG. 1. The same description will not be repeated.

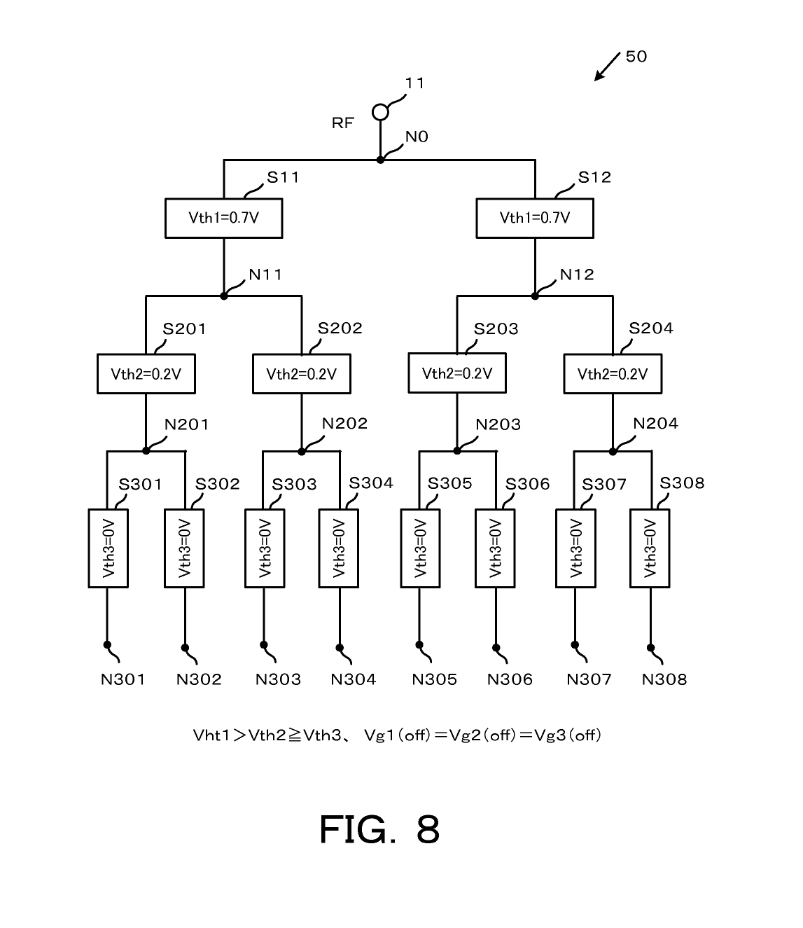

FIG. 8 is a block diagram showing another semiconductor switch circuit with a different tree structure. As shown in FIG. 8, the semiconductor switch circuit 50 has the following tree structure. In the tree structure, two nodes N11 and N12 branch off from a node N0, four nodes N201 to N204 further branch off two by two from each of the two nodes N11 and N12, and eight nodes further branch off two by two from each of the four nodes N201 to N204. The tree structure has three stages.

The threshold Vth1 of MOS transistors 24 of the semiconductor switch unit 50 at the first stage, the threshold Vth2 of MOS transistors 29 of the semiconductor switch unit 50 at the second stage, and the threshold Vth3 of MOS transistors of the semiconductor switch unit 50 at the second stage have the relation defined as

Vth1>Vth2>Vth3 (2)

The semiconductor switch circuit 50 operates as well as the semiconductor switch circuit 10 shown in FIG. 1. The same description will not be repeated. A margin voltage Voff can be given to the MOS transistors 29 at the second stage.

The number of stages in the tree structure is not limited to the number specified in FIG. 8. Except for the semiconductor switch units S11 and S12 nearest to the node N0, all that's required is that the threshold of MOS transistors connected to the side of the node NO is not lower than the threshold of MOS transistors connected to the opposite side of the node NO.

In the above description, a semiconductor switch has a series circuit of MOS transistors, and the number of the series-connected MOS transistors is not limited particularly. Alternatively, just one MOS transistor having a tolerance to voltage amplitude of a high-frequency signal RF may be employed.

In the above description, the first resistance R11 and the second resistance R12 are connected to each MOS transistor 24; and the first resistance R21 and the second resistance R22 are connected to each MOS transistor 29. The semiconductor switches can provide the same result of the embodiment without the resistances R11, R21, R12, and R22.

### Second Embodiment

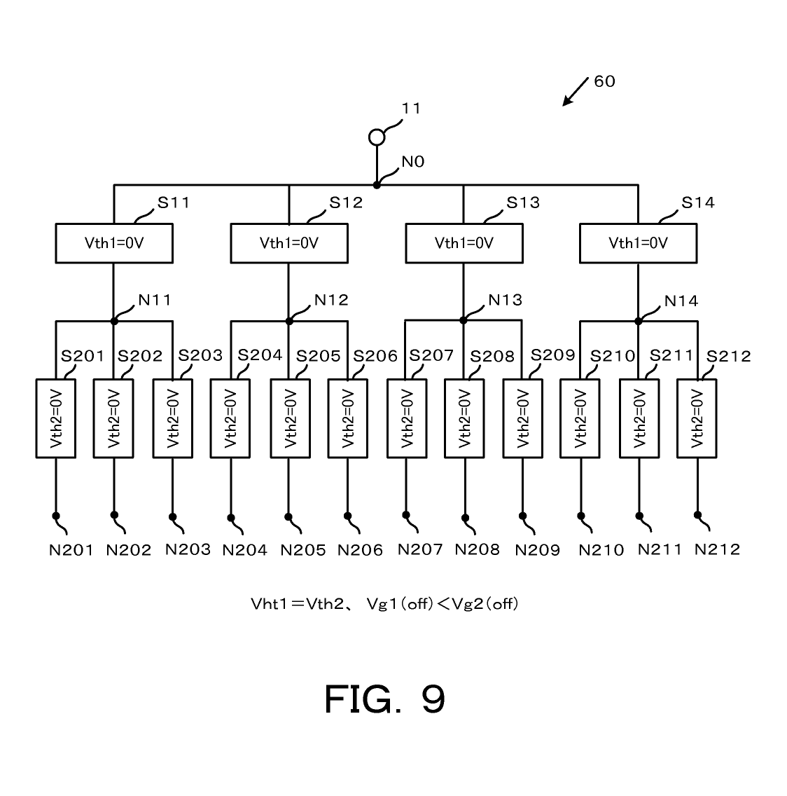

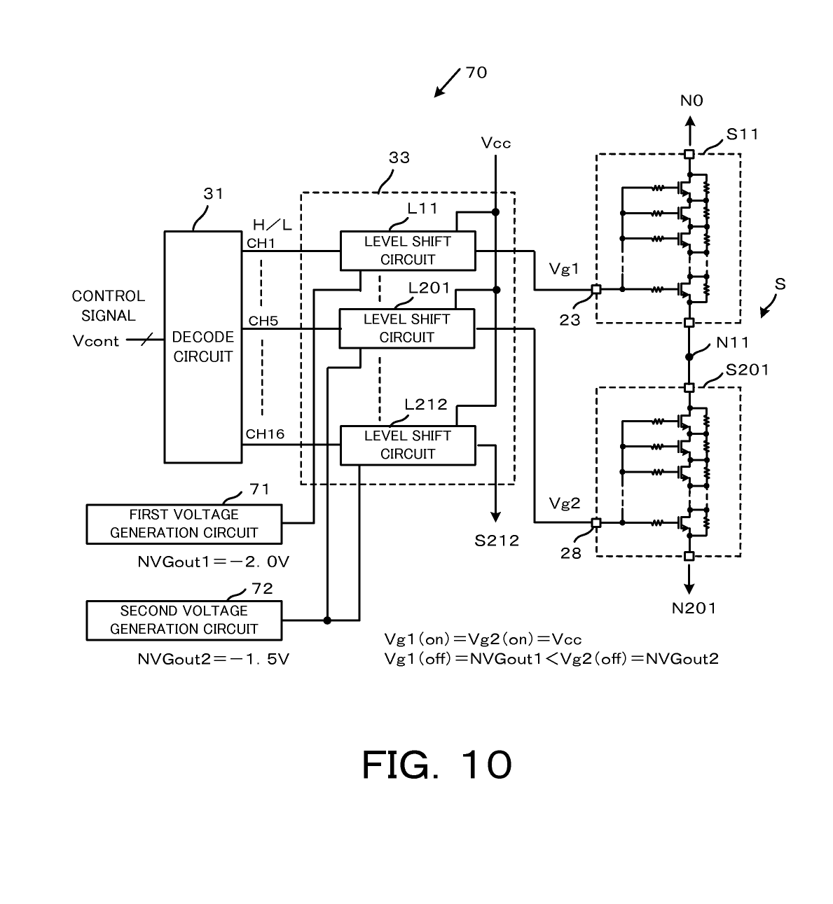

A semiconductor switch circuit in accordance with a second embodiment will be described with reference to FIG. 9 and FIG. 10. FIG. 9 is a block diagram showing the semiconductor switch circuit of the embodiment, and FIG. 10 is a circuit diagram showing a bias circuit.

Wherever possible, the same reference numerals or marks as those in the first embodiment will be used to denote the same or like portions throughout the drawings. The second embodiment differs from the first embodiment in that the thresholds Vth1 and Vth2 are equal to each other, and the gate voltage Vg1(off) (second control voltage) is higher than the gate voltage Vg1(off) (first control voltage).

As shown in FIG. 9, a semiconductor switch circuit 60 is configured as well as the semiconductor switch circuit 10, but the threshold Vth1 of the MOS transistors 24 in the semiconductor switch units S11 to S14 is 0 V, i.e., 0.5 V lower than the threshold Vth1 in the semiconductor switch circuit 10. The threshold Vth2 of MOS transistors 29 in the semiconductor switch units S201 to S212 is 0V, so that the thresholds Vth1 and Vth2 are equal to each other.

As shown in FIG. 10, a bias circuit 70 includes a decoder 31, a voltage output circuit 33, a first voltage generation circuit 71, and a second voltage generation circuit 72. The first voltage generation circuit 71 generates a voltage NVGout1 of −2.0 V to be outputted to level shift circuits L11 to L14. The second voltage generation circuit 72 generates a voltage NVGout2 of −1.5V to be outputted to level shift circuits L201 to L212.

As a result, the gate voltage Vg1(off) (first gate voltage) is set to −2.0 V, and the gate voltage Vg2(off) (second gate voltage) is set to −1.5 V. The gate voltage Vg1(off) is set lower than the gate voltage Vg2(off).

The decrement (0.5 V) of Vth1 and the decrement (0.5 V) of Vg1 are cancelled in accordance with the equation (1), i.e., Voff=Vth1−Vg1−V1, thereby keeping the voltage margin Voff unchanged. As a result, the high-frequency distortion characteristic is acquired in semiconductor switch circuit 60 as well as in the semiconductor switch circuit 10 shown in FIG. 1.

The first voltage generation circuit 71 and the second voltage generation circuit 72 have the same configuration as the voltage generation circuit 32 shown in FIG. 3. The same description will not be repeated.

The threshold Vth1 and the threshold Vth2 are not needed to differ from each other, thereby enabling it to reduce the number of steps of manufacturing the semiconductor switch circuit 60. The first voltage generation circuit 71 and the second voltage generation circuit 72 differ from each other only in the number of stages in respective charge-pump circuits to have no influence on the number of the manufacturing steps.

In the semiconductor switch circuit 60 of the embodiment, the bias circuit 70 includes the first voltage generation circuit 71 to generate a voltage NVGout1 and the second voltage generation circuit 72 to generate a voltage NVGout2, thereby allowing the gate voltage Vg1(off) to be lower than the gate voltage Vg1(off). Also when the threshold Vth1 and the threshold Vth2 are equal to each other, the semiconductor switch circuit 60 provides sufficient margin voltage Voff.

Thus, the semiconductor switch circuit 60 with little high-frequency distortion is achieved. The number of the manufacturing steps for the semiconductor switch circuit 60 is advantageously reduced. In the description, the semiconductor switch circuit 60 includes a tree structure with two stages, but the number of the stages is not limited to this. Except for the semiconductor switch units S11 to S14 nearest to the node N0, all that's required of the semiconductor switch circuit 60 is that the gate voltage applied to off-state MOS transistors connected to the side of the node N0 is not higher than the gate voltage applied to MOS transistors connected to the opposite side of the node N0.

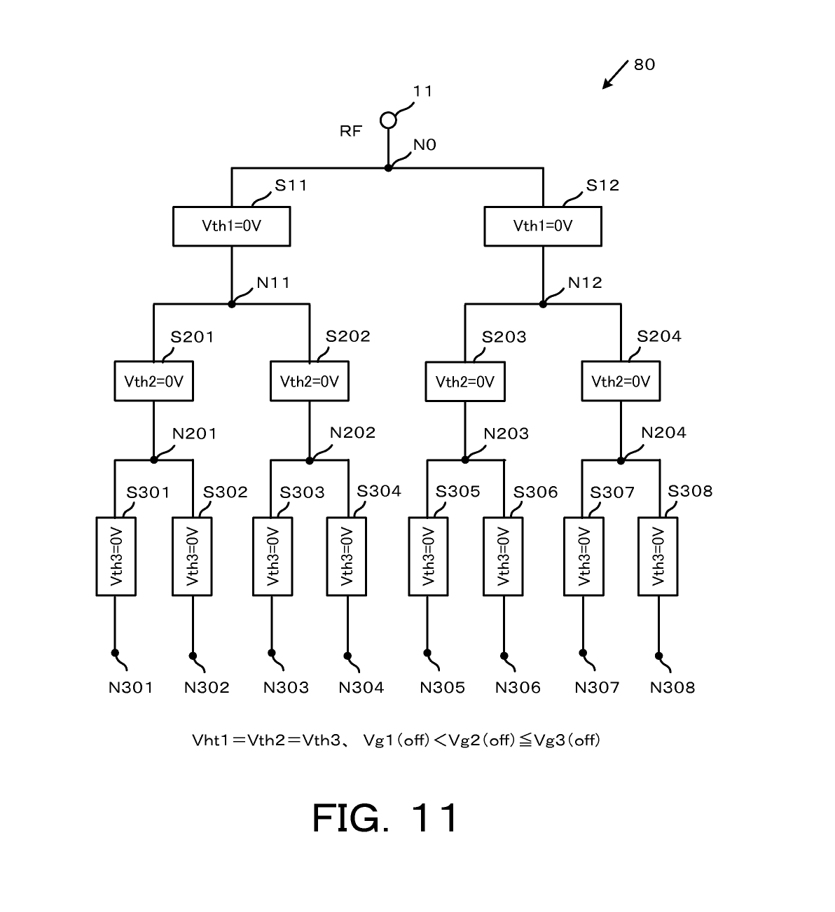

FIG. 11 is a block diagram showing a semiconductor switch circuit with another tree structure. As shown in FIG. 11, the semiconductor switch circuit 80 has the same tree structure as the semiconductor switch circuit 50 shown in FIG. 8.

The different point is that the threshold Vth1 of the MOS transistors 24 at the first stage, the threshold Vth2 of the MOS transistors 29 at the second stage, and the threshold Vth3 of the MOS transistors at the third stage are equal to each other.

The bias circuit (not shown) applies the gate voltage Vg1(off), the gate voltage Vg2(off), and the gate voltage Vg3(off) to the MOS transistors 24 at the first stage, the MOS transistors 29 at the second stage, and the MOS transistors at the third stage, respectively.

The gate voltage Vg1(off), the gate voltage Vg2(off), and the gate voltage Vg3(off) satisfy the following relation as

Vg1(off)<Vg2(off)<Vg3(off) (3)

A bias circuit is achieved by adding a third voltage generation circuit, which generates the gate voltage Vg3(off), to the bias circuit 70.

Alternatively, the bias circuit 70 may be used for the semiconductor switch circuit 10. The semiconductor switch circuit 80 increases the margin voltage Voff of the MOS transistors 24 by the gate voltage Vg1(off) to advantageously increase the margin against lot-to-lot variability of the threshold Vth1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor switch circuit, comprising:
first semiconductor switch units each having a first threshold and two first ends, one first end being connected to a common terminal;
second semiconductor switch units each having a second threshold and two second ends, one second end being connected to the other first end of the first semiconductor switch units, the second threshold being lower than the first threshold.

2. The circuit according to claim 1, wherein
the first semiconductor switch units each have a plurality of insulated gate field effect transistors connected in series; and
the second semiconductor switch units each have a plurality of insulated gate field effect transistors connected in series.

3. The circuit according to claim 2, further comprising:
a first resistance connected to a gate electrode of each of the insulated gate field effect transistors; and
a second resistance connected between a drain electrode and a source electrode of each of the insulated gate field effect transistors.

4. The circuit according to claim 1, further comprising a bias circuit configured to apply the same control voltage to off-state first semiconductor switch units of the first semiconductor switch units and off-state second semiconductor switch units of the second semiconductor switch units.

5. The circuit according to claim 4, wherein the bias circuit includes:
a decode circuit configured to decode states of the first semiconductor switch units and the second semiconductor switch units, to output a low-level signal or a high-level signal in accordance with the states;
a voltage generation circuit configured to generate the control voltage; and
a voltage output circuit configured to shift a voltage level of the low-level signal or the high-level signal to the control voltage level, to output the control voltage to the first semiconductor switch units and the second semiconductor switch units .

6. The circuit according to claim 5, wherein
the voltage generation circuit includes a charge pump circuit and a clock-signal generation circuit.

7. The circuit according to claim 1, further comprising:
a bias circuit configured to apply a first control voltage to off-state first semiconductor switch units of the first semiconductor switch units, and to apply a second control voltage to off-state second semiconductor switch units of the second semiconductor switch units, the second control voltage being higher than the first control voltage.

8. The circuit according to claim 7, wherein
the bias circuit includes:
a decode circuit configured to decode states of the first semiconductor switch units and the second semiconductor switch units to output a low-level signal or a high-level signal in accordance with the states;
a first voltage circuit configured to generate the first control voltage;
a second voltage circuit configured to generate the second control voltage;
a voltage output circuit configured to shift a voltage level of the low-level signal or the high-level signal to the first control voltage level and the second control voltage level, to output the first control voltage to the first semiconductor switch units and the second control voltage to the second semiconductor switch units.

9. The circuit according to claim 8, wherein
the first voltage generation circuit and the second voltage generation circuit each have a charge pump circuit and a clock-signal generation circuit.

10. The circuit according to claim 1, further comprising:
third semiconductor switch units each having a third threshold and two third ends, one third end being connected to the other second end of the second semiconductor switch units, the third threshold being equal to the second threshold or lower than the second threshold.

11. A semiconductor switch circuit, comprising:
first semiconductor switch units each having a first threshold and two first ends, one first end of the first semiconductor switch units being connected to a common terminal;
second semiconductor switch units each having a second threshold and two second ends, one of the two second ends being connected to the other of the two first ends, the second threshold being equal to the first threshold; and
a bias circuit configured to apply a first control voltage to off-state first semiconductor switch units of the first semiconductor switch units, and to apply a second control voltage to off-state second semiconductor switch units of the second semiconductor switch units, the second control voltage being higher than the first control voltage.

12. The circuit according to claim 11, wherein
the first semiconductor switch units each have a plurality of insulated gate field effect transistors connected in series; and
the second semiconductor switch units each have a plurality of insulated gate field effect transistors connected in series.

13. The circuit according to claim 12, further comprising:
a first resistance connected to a gate electrode of each of the insulated gate field effect transistors; and
a second resistance connected between a drain electrode and a source electrode of each of the insulated gate field effect transistors.

14. The circuit according to claim 11, wherein
the bias circuit includes:
a decode circuit configured to decode states of the first semiconductor switch units and the second semiconductor switch units, to output a low-level signal or a high-level signal in accordance with the states;
a first voltage generation circuit configured to generate the first control voltage;
a second voltage generation circuit configured to generate the second control voltage; and
a voltage output circuit configured to shift a voltage level of the low-level signal or the high-level signal to the first control voltage level and the second control voltage level, to output the first control voltage to the first semiconductor switch units and the second control voltage to the second semiconductor switch units.

15. The circuit according to claim 14, wherein
the first voltage generation circuit and the second voltage generation circuit each have a charge pump circuit and a clock-signal generation circuit.

16. The circuit according to claim 11, further comprising:
third semiconductor switch units each having a third threshold and two
third ends, one third end being connected to the other second end of the second semiconductor switch units, the third threshold being equal to the second threshold or lower than the second threshold.
